(19) United States
(12) Patent Application Publication
(10) Pub. No.: US 2026/0089868 A1
(43) Pub. Date: Mar. 26, 2026

(54) CONFIGURABLE CABLE MANAGEMENT DEVICE

(71) Applicant: viaPhoton, Inc., Aurora, IL (US)

(72) Inventors: Wade James WOMACK, Allen, TX (US); Walter Mark HENDRIX, Dallas, TX (US); Mark James SMRHA, Chicago, IL (US); Nathan Eric BENTON, Dallas, TX (US)

(21) Appl. No.: 19/334,416

(22) Filed: Sep. 19, 2025

Related U.S. Application Data
(60) Provisional application No. 63/697,123, filed on Sep. 20, 2024.

(51) Int. Cl. H05K 7/14; F16L 3/10; F16L 3/22

(52) U.S. Cl. CPC H05K 7/1491; F16L 3/10; F16L 3/221

(57) ABSTRACT

A cable management system and method are disclosed for organizing cables at the interface of a panel. A panel assembly integrates the cable management device along the front edge of the panel so that cables routed from the panel remain supported during operation. The system includes a cable management device having a base structure attachable to a front edge of the panel, a set of mounting posts extending from the base structure, and a set of support beams. Each support beam including a receiver removably engaging a respective mounting post and a cable support for guiding cables.

### CROSS-REFERENCE TO RELATED APPLICATIONS

This Application claims the benefit of U.S. Provisional Application Serial No. 63/697,123, filed Sep. 20, 2024, which is hereby incorporated by reference for all purposes.

### BACKGROUND

In modern data centers and network facilities, large volumes of fiber optic and copper cables are installed within racks, panels, and distribution frames. These cables must be organized to ensure proper connectivity between servers, switches, and other active equipment. As transmission rates and port densities increase, the volume of cabling within a limited footprint grows accordingly, placing greater demands on the mechanical infrastructure used to guide and secure the cables. The environment therefore requires routing systems that can manage high densities while maintaining accessibility for installation and maintenance activities.

Conventional cable management practices often rely on static brackets, fixed trays, or simple tie-down arrangements. While these solutions provide initial organization, they do not scale effectively when cables are added, removed, or reconfigured. In many cases, the lack of modularity forces technicians to disturb existing cable runs to introduce new ones, which can increase downtime and risk damage to connectors. Additionally, the limited ability to adjust existing management hardware reduces efficiency during system upgrades or expansions.

Another challenge arises from the need to maintain proper bend radius and clearance for cables exiting panels or modules. If cables are not adequately supported at the interface between active equipment and distribution pathways, excessive strain may be applied to the connectors. This strain can lead to signal degradation or mechanical failure over time. Further, insufficient labeling and identification practices in existing systems complicate the process of tracing or rerouting cables, making troubleshooting more time-consuming and error prone.

### SUMMARY

The present disclosure provides a cable management device that attaches to a front edge of a panel and organizes cables as they exit the panel. The device includes a base structure with a set of mounting posts and a set of support beams. Each support beam has a receiver that removably engages a respective mounting post and a cable support that guides cables outward from the panel. This configuration establishes a modular platform where support beams can be added, removed, or repositioned to suit different routing requirements.

The disclosure further provides a panel assembly that integrates the cable management device along the front edge of a panel. The assembly includes a base structure secured to the panel, mounting posts that extend from the base, and support beams that engage the mounting posts to support cables routed from the panel. The panel assembly ensures that cables are organized at the point of exit and remain supported even as the panel is operated within a tray or rack environment.

A method for managing cables in a panel is also disclosed. The method includes attaching a base structure to the front edge of the panel, mounting support beams onto mounting posts of the base, routing cables across the support beams, and securing the cables in place. Additional steps may include fastening the cables with tie-downs, rotating or removing individual support beams using latch mechanisms, and inserting port identification cards into card slots on the base structure to align cables with specific panel ports.

Other aspects of the invention will be apparent from the following description and the appended claims.

### BRIEF DESCRIPTION OF DRAWINGS

FIG. 1 shows a rack including panels, modules, and cables in a network environment according to an illustrative embodiment.

FIGS. 2A and 2B show views of a panel arrangement within a rack including modules and cable routing features according to an illustrative embodiment.

FIG. 3 shows a panel tray supporting a panel having a cable management device secured to a front edge according to an illustrative embodiment.

FIGS. 4A and 4B show views of the cable management device including a base structure, mounting posts, and support beams according to an illustrative embodiment.

FIGS. 5A and 5B show detailed views of a support beam including a receiver, a cable support, a beam flange, a latch lock, and a latch release according to an illustrative embodiment.

FIGS. 6A and 6B show views of the base structure including card slots and port identification cards according to an illustrative embodiment.

FIG. 7 shows a flowchart of a process for managing cables in a panel according to an illustrative embodiment.

Like elements in the various figures are denoted by like reference numerals for consistency.

### DETAILED DESCRIPTION

The illustrative embodiments provide for a cable management device. The disclosed cable management device introduces a modular base structure that attaches directly to the front edge of a panel, creating an integrated interface between the panel and the external cable environment. Unlike fixed or static systems, the base structure incorporates mounting posts that allow support beams to be selectively attached or removed. The embodiments enable a configurable arrangement of cable supports, permitting users to adapt the device to specific routing requirements without modifying the panel or rack infrastructure.

Each support beam incorporates a receiver for engaging the mounting post, a latch mechanism for securing or releasing the connection, and a flange at the distal end of the beam for retaining tie-downs. The combination of features allows beams to be installed, repositioned, or removed with minimal effort, while still ensuring that cables remain supported along defined pathways. The ability to rotate or detach beams by actuating a latch release provides controlled access to underlying cables and connectors, addressing challenges associated with maintenance and reconfiguration in dense environments.

The system also integrates labeling, and identification features directly into the base structure. Card slots are positioned along the base to accept port identification cards, allowing cables secured to each support beam to be correlated with panel connections. The labeling and identification features improve clarity during installation and troubleshooting by aligning physical cable organization with logical port assignments. Together, the modular support beams and integrated identification system provide a scalable and serviceable approach to managing high-density cabling at the panel interface.

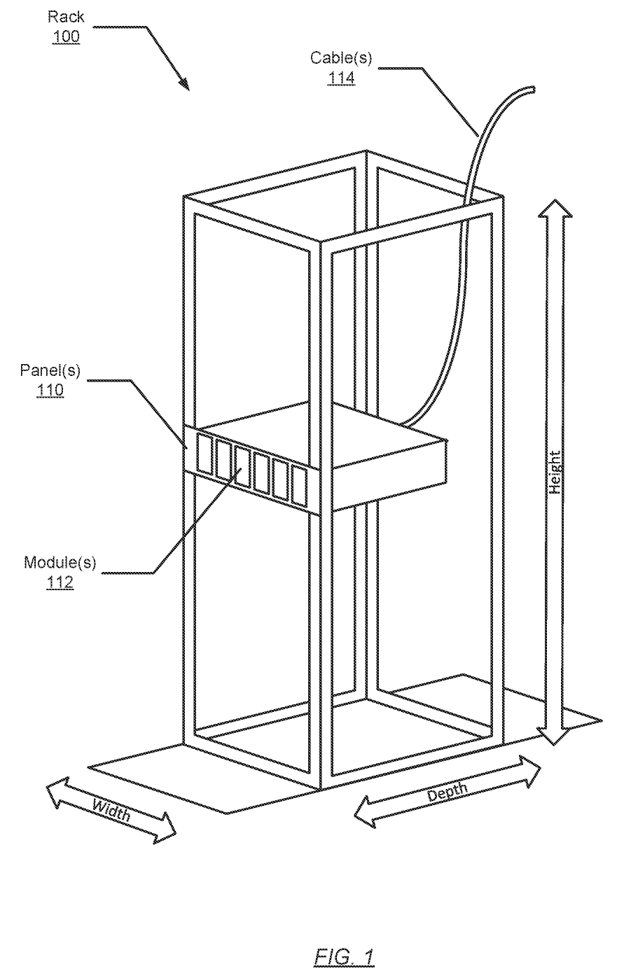

Turning to FIG. 1, a rack is shown in accordance with one or more embodiments. The rack (100) is a piece of telecommunications equipment that provides for the housing and organization of diverse telecommunication devices.

The outer dimensions of rack (100) conform with most network and server equipment. For example, rack width may measure 19 inches (48.26 cm) or 23 inches (58.42 cm) in width, standard measurements that are adhered to in the telecommunications industry. Other dimensions may be used, e.g., 21 inches, 23 inches, etc. The dimensions ensure that the rack can accommodate equipment with different form factors, such as 1U, 2U, or larger units, where "U" represents a standard rack unit of measure equal to 1.75 inches in height.

The rack (100) may include a series of uniformly spaced vertical mounting slots, located on both the front and rear, to facilitate the arrangement and mounting of various telecommunication devices and components. The slots serve as attachment points for mounting the panel(s) (110). The rack (100) may further be equipped with additional features such as ventilation openings and cable management.

Panel(s) (110) are components that mount within the rack (100) to organize, secure, and provide access to connective hardware. The panel may be constructed from materials such as steel or aluminum that can support the weight of the modules and withstand the physical demands of a data center environment.

Panel(s) (110) are formed with standardized form factors for compatibility with the mounting slots of the rack (100). For example, panel(s) (110) may include standardized mounting points to align with rack units, a layout that supports the intended cable or connector density, and provisions for labeling and user accessibility.

The panel(s) (110) may be equipped with one or more module(s) (112) to secure the fibers using ports, connector adapters, connectors, etc. Module(s) (112) are prefabricated units or sub-assemblies configured for quick installation into the rack (100). The module(s) (112) may include electronic components and/or optical components, such as optical connectors, optical fibers, switches, routers, or patches. The module(s) (112) may include features for splicing, cable management, and security.

Each module(s) (112) is configured to contain a specific number of optical connectors, optimizing space utilization within the rack mount to support high fiber densities. For example, each module(s) (112) may support fiber densities of 144 fibers, 288fibers, and/or 576 fibers per module, as well as other suitable densities. The connectors may be an industry-standard connector such as a standard connector (SC), Lucent connector (LC), or Multi-fiber Termination Push-on connector (MTP), depending on the network requirements.

The module(s) (112) may have multiple widths, such that a varying number of modules may be housed within the panel(s) (110). The module(s) (112) may be sized to fit twelve (12) modules in the panel(s) (110), however other sizes – e.g., 2, 3, 4, 6, 8 - are also contemplated. When fully loaded with module(s) (112), the panel(s) (110) support fiber densities of 1728 fibers, 3456, fibers, and/or 6912 fibers per panel, as well as other suitable densities.

Cable(s) (114) may be fiber optic cables that carry data signals between different network devices and components. Cable(s) (114) are routed through the data center infrastructure, connecting panels, modules, and external devices. For example, cable(s) (114) may interconnect module(s) (112). Cable(s) (114) may include a core, cladding, and protective coating, which ensure the integrity of the data signal. Cable(s) (114) can be single-mode or multi-mode, depending on the network requirements. Cable(s) (114) may be color-coded to facilitate identification during installation and maintenance.

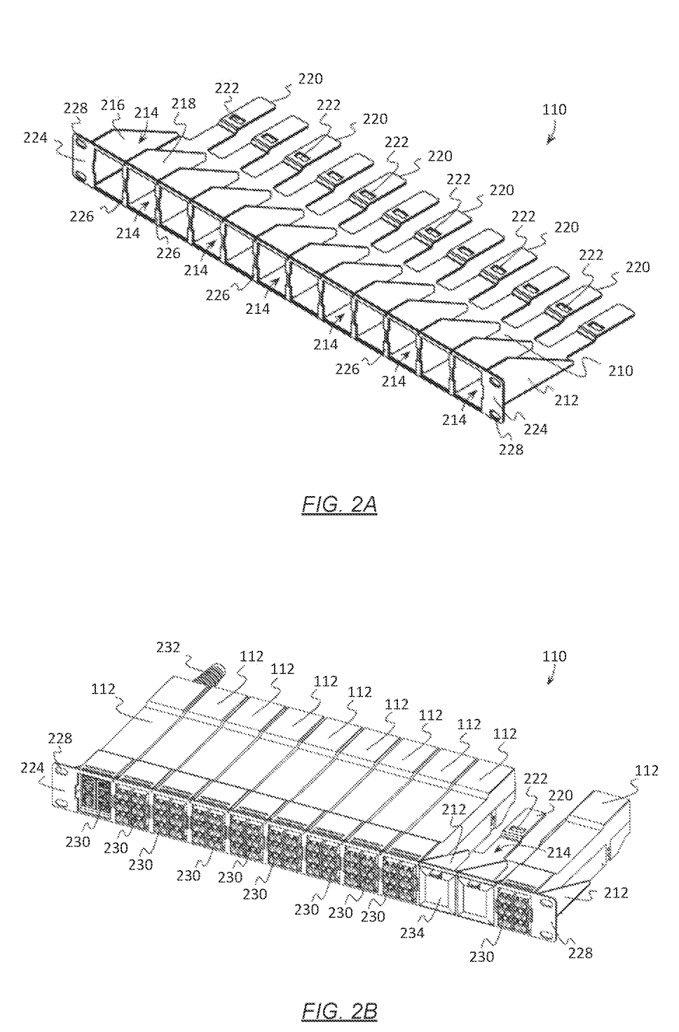

FIGS. 2A and 2B illustrate an example of a panel equipped with one or more modules, according to various embodiments. The panel and modules are panel(s) (110) and module(s) (112) of FIG. 1.

The panel(s) (110) may comprise a frame base (210) to which two or more dividers (212) may be coupled. Preferably, the frame base (210) and the dividers (212) may each be generally planar or flat in shape. The dividers (212) may be oriented generally perpendicular to the frame base (210). Optionally, two or more of the dividers (212) may be oriented generally parallel to each other, and preferably each of the dividers (212) of a panel(s) (110) may be oriented generally parallel to each other. The elements of the panel(s) (110) may be made from or may comprise durable materials such as various types of stamped sheet metal, plastics, carbon fiber, or any other generally rigid material.

An alignment slot (214) may be formed and bounded by two adjacent dividers (212), such as a first divider (216) and a second divider (218) , and by portions of the frame base (210) extending between the two adjacent dividers (212). For example, thirteen dividers (212) may be coupled to a frame base (210) to form twelve alignment slot (214). In some embodiments, a first divider (216) and second divider (218) may be separated by a distance that is slightly greater than the width of the module(s) (112) so that the module(s) (112) may be snugly or received in the alignment slot (214) between the two adjacent dividers (212).

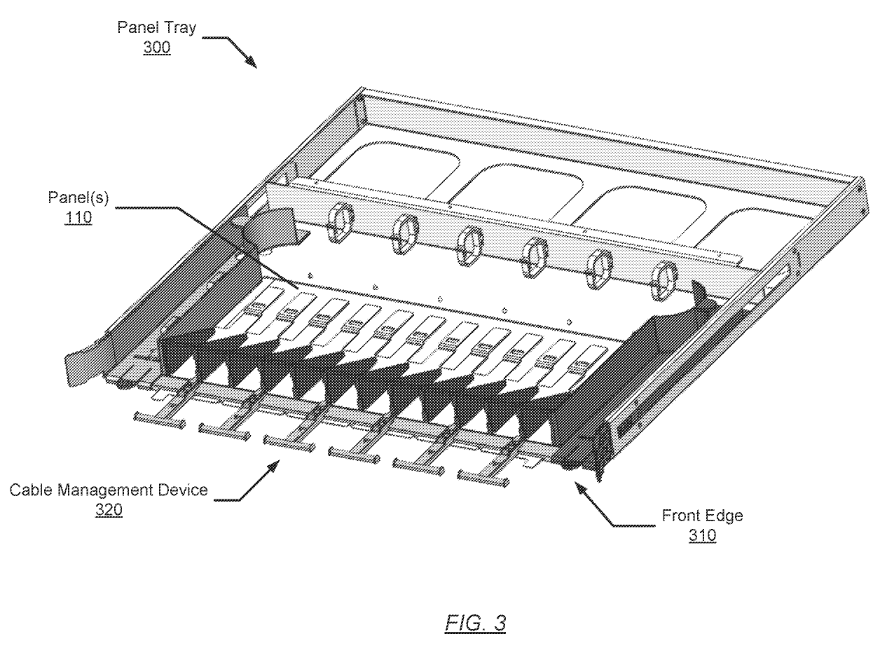

The dividers (212) may be configured in any shape and size. In some embodiments, one or more of the dividers (212) may be configured with a generally triangular shape. In preferred embodiments, one or more of the dividers (212) may comprise a generally right trapezoid shape having two adjacent right angles and two parallel sides as shown in FIGS. 3A and 3C. In other embodiments, one or more of the dividers (212) may comprise a generally square shape, half circle shape, rectangular shape, or any other shape.

The panel(s) (110) may comprise one or more key(s) (220) which may be coupled to, optionally by being integrally formed with, the frame base (210). In some embodiments, a key(s) (220) may be coupled to a frame base (210) so that the key(s) (220) may extend away from an alignment slot (214) of the panel(s) (110). In preferred embodiments, each key(s) (220) may be coupled to a frame base (210) so that each key(s) (220) may extend away from a respective alignment slot (214) of the panel(s) (110). In further preferred embodiments, the panel(s) (110) may comprise a key(s) (220) extending away from each alignment slot (214).

Each key(s) (220) may comprise a key aperture (222) which may be positioned anywhere on the key(s) (220). In some embodiments, all, or portions of a key(s) (220) may be movable relative to the frame base (210). In preferred embodiments, the portion of the key(s) (220) having the key aperture (222) may be movable relative to the frame base (210). Optionally, the key(s) (220) and/or frame base (210) may be made from a flexible material, such as a sheet of plastic or metal, which may allow the portion of the key(s) (220) having the key aperture (222) to be movable relative to the frame base (210). In other embodiments, any movable coupling may be used to enable the portion of the key(s) (220) having the key aperture (222) to be movable relative to the frame base (210), such as any type of hinge or movable fastener. By being movable, the key aperture (222) may be moved into and out of contact with a lock tab of a module(s) (112) that is received in a respective alignment slot (214).

In some embodiments, the panel(s) (110) may comprise a face plate (224) which may be coupled to one or more dividers (212), frame base (210), or other element of the panel(s) (110). A face plate (224) may comprise a number of gate(s) (226), in which each gate(s) (226) may form and bound the entrance of an alignment slot (214) opposite the key(s) (220) of the alignment slot (214). In some embodiments, a face plate (224) may comprise one or more, and preferably four securement aperture(s) (228) which may be sized and shaped to receive one or more fasteners, such as screws, bolts, other threaded fasteners, or any other type 0.09 of fastener, which may be used to secure the panel(s) (110) to rack (100) of FIG. 1.

Each alignment slot (214) may be configured to received one or more module(s) (112). In some embodiments, a module(s) (112) may be secured or coupled to the panel(s) (110) via engagement with a key aperture (222). For example, a module(s) (112) may be secured or coupled to the panel(s) (110) via engagement between a lock tab on the module(s) (112) with a key aperture (222) of a key (220).

The module(s) (112) may secure one or more cables to their respective cable coupling(s) (230) and/or strain relief (232). In some embodiments, a blanking plug (234) may be coupled to module(s) (112) to prevent dirt, contaminants, unwanted access, etc. the module(s) (112) and any cable connectors (230) positioned in the module(s) (112).

FIGS. 3 is a panel tray according to illustrative embodiments. The panel tray may contain a panel and one or more modules comma such as panel(s) (110) and module(s) (112) of FIG. 1.

Panel tray (300) is positioned to receive panel (110) and provides a structural boundary that maintains alignment of the panel within rack (100). The tray defines lateral surfaces that guide insertion and removal of the panel. Panel (110) rests within the tray and is supported along its lower surface to prevent vertical displacement during operation.

Front edge (310) of panel (110) is oriented toward the forward opening of tray (300). This edge establishes a linear interface that extends across the width of the panel. In FIG. 3, the front edge is shown as the location of attachment for cable management device (320). The edge also defines the point of transition where cables (114) exit from within panel (110).

Cable management device (320) is mounted along the front edge (310) of panel (110). Device (320) extends outward from the plane of the panel and occupies a position between panel (110) and the routing path of cables (114). The device engages directly with front edge (310) and is arranged to maintain contact along the full span of the edge.

Cables (114) are shown extending from modules (112) located within panel (110). After exiting the modules, the cables are directed toward the front edge (310) where they enter the region defined by cable management device (320). Within this region, the cables are supported so that they do not cross over each other as they are routed away from panel (110). The relative position of device (320) to panel (110) ensures that the cables are organized at the point of exit.

The spatial relationship between tray (300), panel (110), and cable management device (320) enables panel (110) to be displaced forward or rearward within tray (300) while cables (114) remain constrained by the device. The device thereby provides a fixed routing path relative to front edge (310) while accommodating panel movement inside tray (300). The arrangement also maintains access to modules (112) by holding cables (114) outward from the module locations.

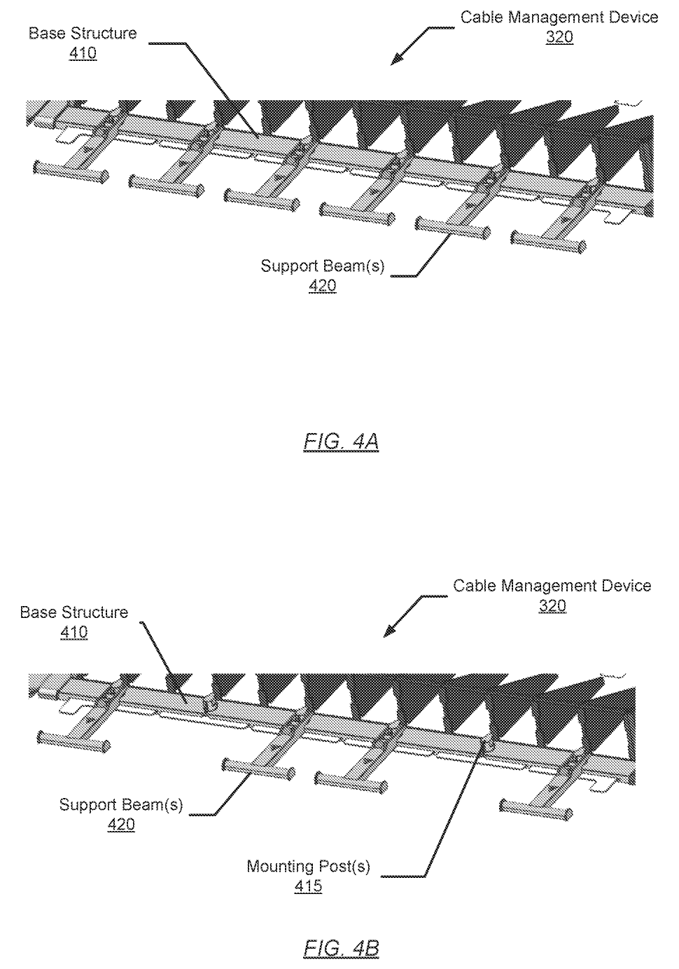

FIGS. 4A and 4B, shown a base structure according to illustrative embodiments.

Base structure (410) extends along the front edge (310) of panel (110) and forms the primary body of cable management device (320). The base structure is shown as a linear component positioned parallel to front edge (310). The base structure defines a rigid platform from which mounting posts (415) extend and provides the structural foundation for attaching support beams (420). The base structure spans across the width of panel (110) to maintain uniform spacing of the mounting posts.

Mounting posts (415) project forward from base structure (410). Each mounting post is aligned orthogonally to the base structure and establishes a discrete location for securing a support beam (420). In the figure, the mounting posts are shown distributed at intervals across the length of the base structure. The orientation of the mounting posts enables support beams to be attached in a forward-facing direction relative to panel (110).

Support beams (420) extend outward from base structure (410) by engaging with respective mounting posts (415). Each support beam is positioned perpendicular to the base structure and projects away from panel (110). In the context of FIGS. 4A and 4B, the support beams define the primary routing surfaces for cables (114) as they emerge from panel (110). The spacing of support beams across the base structure permits distribution of cables into separate paths.

Cable management device (320) is illustrated in assembled form with base structure (410), mounting posts (415), and support beams (420) integrated into a single arrangement. The device is secured to front edge (310) of panel (110) such that the support beams extend into the workspace in front of the panel. The interaction of these elements provides a modular assembly where each support beam may be engaged or disengaged independently while the base structure remains fixed to the panel.

The figure further illustrates how the orientation of support beams (420) relative to mounting posts (415) defines an ordered pattern for cable routing. As cables (114) exit panel (110), they are placed across the support beams. The support beams provide separation that prevents overlapping of cables and maintains consistent routing paths. The base structure ensures that the spacing between support beams is maintained regardless of whether the panel is in a fixed or displaced position relative to panel tray (300).

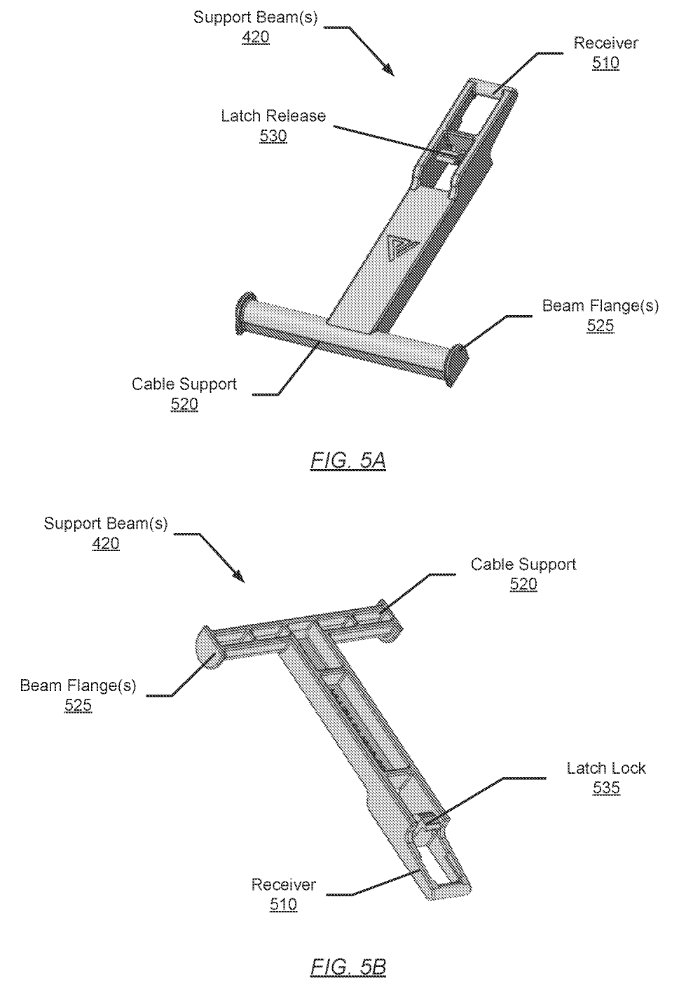

Referring now to FIGS. 5A and 5B, the support beam as shown according to illustrative embodiments.

Receiver (510) is located at a first end of support beam (420) and defines the interface between the support beam and mounting post (415). the receiver is shown as an opening that partially circumscribes the mounting post to establish a removable connection. The geometry of the receiver allows the support beam to be placed onto or removed from the mounting post without additional fasteners.

Cable support (520) extends from receiver (510) toward a distal end of support beam (420). In the figure, the cable support provides a surface along which cables (114) are routed after exiting panel (110). The cable support maintains the orientation of the cables in a direction away from the front edge (310) of the panel and defines the span of the support beam.

Beam flange (525) is positioned at the distal end of cable support (520). The flange extends laterally to create a boundary that prevents fasteners, such as tie-downs, from sliding off the end of the support beam. In use, cables (114) may be secured to cable support (520) with a tie-down looped against beam flange (525).

Latch lock (535) is integrated into support beam (420) adjacent to receiver (510). The latch lock engages with mounting post (415) to secure the receiver in place once the support beam is positioned. In FIG. 5B, the latch lock is shown as a feature that protrudes into the receiver to hold the support beam against the mounting post.

Latch release (530) is provided on support beam (420) in proximity to latch lock (535). The latch release allows disengagement of the latch lock by manual deflection. In operation, a user can press the latch release to move latch lock (535) out of engagement with the mounting post, enabling removal or repositioning of the support beam.

The interaction of receiver (510), cable support (520), beam flange (525), latch lock (535), and latch release (530) form a modular assembly. The receiver provides initial engagement with mounting post (415), while the latch lock maintains the attachment under load. The latch release allows selective disengagement, and the beam flange supports retention of tie-downs used to secure cables. Together, these features define the functional characteristics of each support beam (420) within cable management device (320).

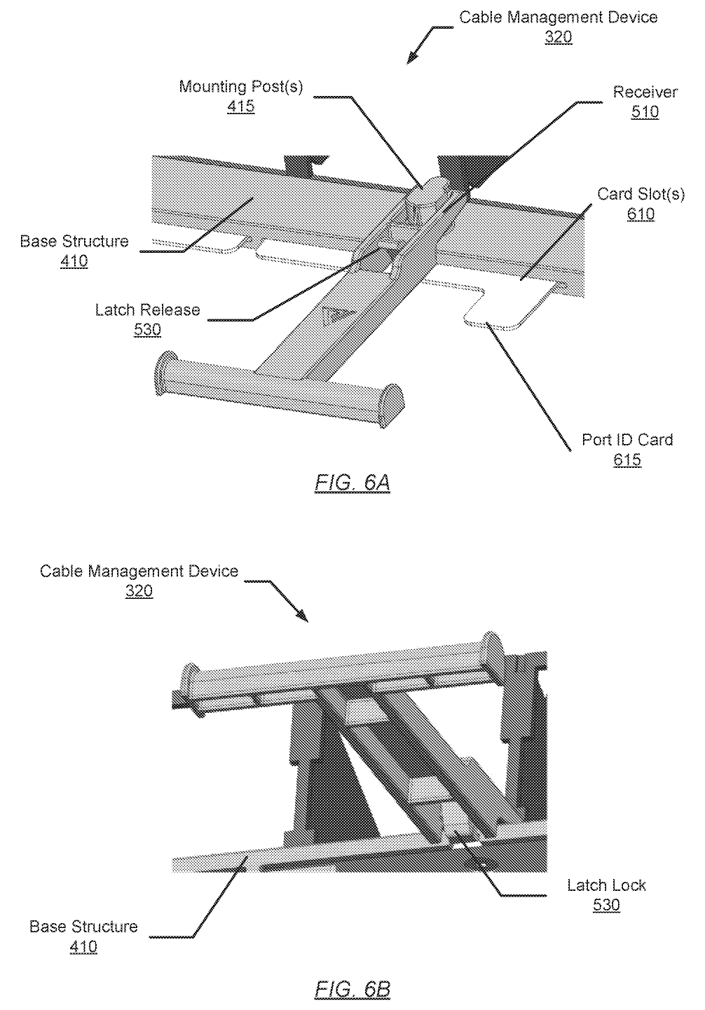

Referring now to FIGS. 6A and 6B, the base structure is depicted in greater detail to show additional features beyond mounting posts (415). Base structure (410) extends along front edge (310) of panel (110) and provides the mounting platform for support beams (420). The base structure is configured with openings and surfaces that support accessory elements associated with identification and labeling of cable connections.

Card slots (610) are formed within base structure (410). Each card slot is dimensioned to receive and retain a port ID card (615). The card slots are aligned along the length of the base structure in positions corresponding to the mounting posts (415) and associated support beams (420). This placement allows direct correlation between each support beam and a corresponding identification marker.

Port ID card (615) is an insertable element positioned within a card slot (610). In FIG. 6B, the card is shown partially engaged with the slot to illustrate its removable nature. The port ID card provides a physical surface for displaying information such as port numbers or cable identifiers. Multiple cards may be used across the base structure, enabling a technician to assign labels to each support beam location.

The interaction of card slots (610) and port ID cards (615) integrates labeling functionality into base structure (410). When a card is inserted into a slot, it is aligned with the support beam associated with that slot. This arrangement allows identification data to be directly correlated to the routing of cables (114) on support beams (420). The base structure therefore supports both the mechanical organization of cables and the informational labeling of corresponding ports.

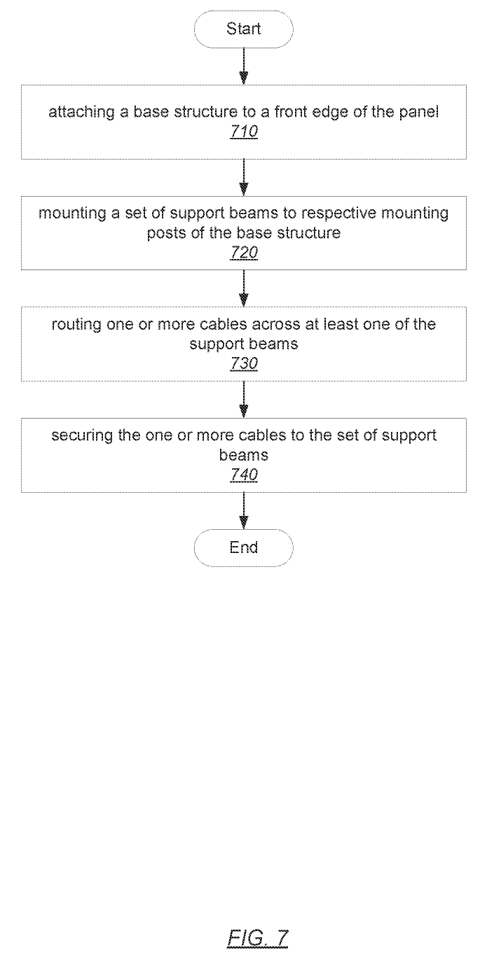

Turning now to FIG. 7, a method for managing cables in a panel is shown in accordance with one or more embodiments of the invention. The method may be performed using one or more of the components illustrated in FIGS. 1-6.

At Step 710, a base structure is attached to a front edge of a panel. The base structure can be base structure (410) of FIG. 4.The base structure is positioned to align with the edge and secured using fasteners that extend through the panel and into hollows formed in mounting posts. Once attached, the base structure defines the mounting platform for subsequent placement of support beams and establishes the point of transition for cables as they exit the panel.

At Step 720, a set of support beams is mounted to respective mounting posts of the base structure. The support beams can be support beams (420) of FIG. 4. Each support beam is installed by positioning a receiver around a corresponding mounting post. A latch lock engages the post to hold the support beam in place, and a latch release can be actuated to remove or reposition the beam. Mounting the set of support beams creates an array extending outward from the front edge of the panel.

At Step 730, one or more cables are routed across at least one of the support beams. After exiting modules within the panel, the cables are directed outward and positioned along the cable support of each beam. Routing in this manner maintains separation of individual cables and directs them away from the panel. A beam flange at the distal end of each support beam constrains tie-downs used in a later securing step.

At Step 740, the one or more cables are secured to the set of support beams. A tie-down or equivalent fastener is looped around the cable support and positioned against the beam flange. Securing the cables prevents movement of the cables relative to the support beams and maintains controlled bend radii. In some embodiments, port identification cards may be inserted into card slots of the base structure to identify and correlate the secured cables with respective ports of the panel.

In the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements.

Further, unless expressly stated otherwise, “or” is an “inclusive or” and, as such includes “and.” Further, items joined by an or may include any combination of the items with any number of each item unless expressly stated otherwise.

The figures of the disclosure show diagrams of embodiments that are in accordance with the disclosure. The embodiments of the figures may be combined and may include or be included within the features and embodiments described in the other figures of the application. The features and elements of the figures are, individually and as a combination, improvements to the technology of keyword extraction using tags and n-grams. The various elements, systems, components, and steps shown in the figures may be omitted, repeated, combined, and/or altered as shown from the figures. Accordingly, the scope of the present disclosure should not be considered limited to the specific arrangements shown in the figures.

In the above description, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description. Further, other embodiments not explicitly described above can be devised which do not depart from the scope of the invention as disclosed herein. Accordingly, the scope of the invention should be limited only by the attached claims.

What is claimed is:

1. A cable management device comprising:
a base structure configured to attach to a front edge of a panel, the base structure comprising a set of mounting posts extending from the base structure; and
a set of support beams, each support beam comprising
a receiver configured to removably engage a respective mounting post; and
a cable support configured to support a set of cables.

2. The cable management device of claim 1, wherein the base structure and the mounting posts are integrally formed as a single molded body.

3. The cable management device of claim 1, wherein the set of support beams are selectively removable from the base structure to provide a configurable arrangement.

4. The cable management device of claim 1, wherein the cable support is configured as a T-shaped member for routing the one or more cables.

5. The cable management device of claim 1, wherein each support beam further comprises:
a beam flange at an end of the cable support, the beam flange configured to retain a fastener securing the set of cables to the cable support.

6. The cable management device of claim 1, wherein each support beam further comprises:
a latch lock configured to secure the receiver to the base structure.

7. The cable management device of claim 6, wherein the support beam is rotatable relative to the respective mounting post when the latch lock is disengaged.

8. The cable management device of claim 6, wherein each support beam further comprises:
a latch release configured to disengage the latch lock from the base structure.

9. The cable management device of claim 8, wherein the latch release is manually deflectable to release the support beam from the base structure.

10. The cable management device of claim 1, wherein the base structure further comprises a set of card slots configured to receive a port identification card.

11. A panel assembly comprising:
a panel having a front edge; and
a cable management device coupled to the front edge, the cable management device comprising:
a base structure secured to the front edge of the panel;
a set of mounting posts extending from the base structure; and
a set of support beams, each support beam comprising a receiver configured to removably engage a respective mounting post and a cable support configured to support one or more cables routed from the panel.

12. The panel assembly of claim 11, wherein the base structure is attached to the front edge of the panel by a set of screws received into hollows of the mounting posts.

13. The panel assembly of claim 11, wherein each support beam further comprises a latch lock configured to secure the support beam to the base structure and a latch release configured to disengage the latch lock.

14. The panel assembly of claim 11, wherein each support beam further comprises a beam flange configured to retain a tie-down securing the one or more cables.

15. The panel assembly of claim 11, wherein the base structure further comprises a set of card slots configured to receive port identification cards corresponding to connections on the panel.

16. A method of managing cables in a panel, the method comprising:
attaching a base structure to a front edge of the panel;
mounting a set of support beams to respective mounting posts of the base structure;
routing one or more cables across at least one of the support beams; and
securing the one or more cables to the set of support beams.

17. The method of claim 16, wherein securing the one or more cables comprises:
fastening the one or more cables with a tie-down coupled to a beam flange of the at least one support beam.

18. The method of claim 16, wherein mounting the support beams further comprises:
positioning the receivers of the support beams around a respective mounting post;
rotating the support beams relative to the respective mounting post; and
engaging a latch lock to secure the support beam to the base structure.

19. The method of claim 16, further comprising removing a selected support beam from the base structure, the removing including:
actuating a latch release to disengage a latch lock and.
rotating at least one of the support beams relative to a respective mounting post.

20. The method of claim 16, further comprising:
inserting a port identification card into a card slot of the base structure.
